(19) United States
(12) Patent Application Publication
(10) Pub. No.: US 2011/0311724 A1
(43) Pub. Date: Dec. 22, 2011

(54) PROVIDING GAS FOR USE IN FORMING A CARBON NANOMATERIAL

(75) Inventors: Ben Poul Jensen, East Sussex (GB); Guan Yow Chen, Singapore (SG)

(73) Assignee: SURREY NANOSYSTEMS LTD, NEWHAVEN (GB)

(21) Appl. No.: 13/146,439

(22) PCT Filed: Jan. 28, 2010
(86) PCT No.: PCT/GB2010/000130

§ 371 Date: Sep. 9, 2011

(30) Foreign Application Priority Data
Jan. 28, 2009 (GB) 09014093

(51) Int. Cl. C23C 16/26; C23C 16/52; C23C 16/455; B82Y 40/00

(52) U.S. Cl. 427/249.1; 118/722; 977/842

(57) ABSTRACT

In a Chemical Vapour Deposition (CVD) process for forming carbon nanomaterials, a supply of acetylene gas is filtered by a filter to remove a volatile hydrocarbon gas before the acetylene gas is provided to a mass flow controller. The mass flow controller can mix the filtered acetylene gas with a supply of the volatile hydrocarbon gas so that a gas mixture has a selected proportion of the volatile hydrocarbon gas. The filter performs the filtering by passing the acetylene gas over active carbon.

### FIELD OF THE INVENTION

This invention relates to providing gas for use in a method of chemical vapour deposition (CVD), and in a CVD apparatus, for forming a carbon nanomaterial. Typically, the carbon nanomaterial is a carbon nanotube (CNT).

### BACKGROUND TO THE INVENTION

Carbon nanomaterials, such as carbon nanotubes (CNTs), can be formed by chemical vapour deposition (CVD). By selecting conditions of CVD under which CNTs are formed, the properties of the CNTs can be controlled. However, the repeatability of CNT formation can depend on a variety of factors. Even under apparently identical selected conditions of CVD, the properties of the CNTs that are formed on one occasion can vary significantly from the properties of the CNTs that are formed on another occasion. The process of CNT formation is apparently therefore sensitive to very small variations in the conditions of CVD under which they are formed. This is very problematic when seeking to manufacture CNTs on an industrial scale.

Acetylene is a common (C₂H₂) constituent of feedstock gases used in CVD to form CNTs. Acetylene is usually stored in acetone (CH₃COCH₃). More specifically, acetylene gas is dissolved in acetone liquid absorbed in a porous material inside a pressurised vessel. This means that as acetylene gas is extracted from the vessel, some acetone gas is also usually extracted with it at the same time. In some examples, other volatile hysdrocarbons are used in place of acetone for this purpose. For example, dimethylformamide ((CH3)2NC(O)H) has been used in place of acetone.

It has been suggested to filter the feedstock gas used in CVD to form CNTs. In the paper “Synthesis of Nanotubes via Catalytic Pyrolysis of Acetylene: a SEM Study”, Muller et al, Carbon Vol. 35, No. 7, pp 951-966, 1997, it is suggested to separate acetylene gas from acetone gas by passage through a trap immersed in dry ice (i.e. solid carbon dioxide (CO₂)). The acetylene gas is then bubbled through concentrated sulphuric acid (H₂SO₄) to remove impurities. Likewise, in the paper “Interactions between acetylene and carbon nanotubes at 893 and 1019 K”, Xu et al, Carbon Vol. 39, pp 1835-1847, 2001, it is suggested to use pre-purified acetylene gas, which is less than 30,000 parts per million (ppm) acetone, and to pass this pre-purified acetylene gas through a isopropanol (C₃H₈O)/dry ice trap to reduce the mole fraction of acetone, ethane (C₂H₆), ethylene (C₂H₄) and propylene (C₃H₆). However, the effect of the presence, absence or amount of acetone gas in the feedstock gas on CNT formation is not considered in either of these papers. These papers also fail to recognise that the relative proportion of acetylene gas and acetone gas extracted from the vessel in which they are stored varies according to the pressure and temperature inside the vessel, both of which can be affected by external influences such as changes in ambient temperature or the amount of acetylene and acetone remaining in the vessel. Even with the filtering described in these papers, the relative proportions of acetylene gas and acetone gas in the feedstock gas will vary significantly due to these external influences, hampering repeatability of CNT formation. Furthermore, as the sublimation point of dry ice is around minus 78.5° C. and the boiling point of acetylene is around minus 84° C., there is a significant risk that the traps will condense acetylene in addition to acetone during the separation. Acetylene is highly unstable in liquid form, making the use of the described traps very dangerous. Moreover, depending on the manner in which the acetylene has been manufactured, a number of impurities are likely to be present, and these may also prove hazardous when isolated in a trap of this type. For example, acetylene formed from a combination of calcium carbide and water has been found to include a wide range of impurities, such as: water, carbon dioxide, hydrogen, methane, silicon hydrides, arsine, phosphine, ammonia, hydrogen sulphide and organic sulphur compounds.

The present invention seeks to overcome these problems.

### SUMMARY OF THE INVENTION

According to a first aspect of the present invention, there is provided a method of chemical vapour deposition for forming a carbon nanomaterial, the method comprising:

filtering a supply of acetylene gas to remove a volatile hydrocarbon gas;

mixing the filtered supply of acetylene gas with a supply of the volatile hydrocarbon gas to provide a gas mixture having a selected proportion of the volatile hydrocarbon gas;

providing the gas mixture to a chamber; and

performing chemical vapour deposition in the chamber to form the carbon nanomaterial with use of the gas mixture.

According to a second aspect of the present invention there is provided chemical vapour deposition apparatus for forming a carbon nanomaterial, the apparatus comprising:

a filter for filtering a supply of acetylene gas to remove a volatile hydrocarbon gas;

a mass controller for mixing the filtered supply of acetylene gas with a supply of the volatile hydrocarbon gas to provide a gas mixture having a selected proportion of the volatile hydrocarbon gas; and

an inlet for providing the gas mixture to a chamber so that chemical vapour deposition can be performed in the chamber to form the carbon nanomaterial with use of the gas mixture.

So, the invention allows proper control of the amount of the volatile hydrocarbon gas in the gas mixture used for carbon nanomaterial formation. The volatile hydrocarbon gas present in the supply of acetylene gas can be fully removed. A selected amount of the volatile hydrocarbon gas can then, if required, be mixed with the acetylene gas. Hence, the relative proportions of acetylene gas and the volatile hydrocarbon gas can be selected independently of external influences. This significantly improves the repeatability of the formation of the carbon nanomaterial.

The volatile hydrocarbon gas may be any substance in which acetylene may be stored. In some examples, the volatile hydrocarbon gas is dimethylformamide ((CH3)2NC(O)H) gas. However, more commonly the volatile hydrocarbon gas is acetone gas.

It has been found that the variation in the proportions of acetylene and acetone present in conventional supplies of acetylene can be dramatic, and that this substantially alters the conditions in which CVD takes place. For example, it has been found in a particular case that an acetylene supply vessel provided a concentration of acetone two orders of magnitude higher than that of acetylene when initially turned on (after a rest period of more than a week), but two hours later provided a significantly lower acetone concentration than acetylene concentration. The proportions of acetylene and acetone delivered can also vary substantially if the supply vessel is stored in an uncontrolled environment, such as in the open air during hot or cold weather. As a result, the conditions in which CVD takes place are unstable, leading to a lack of repeatability and reduced yields. The present invention addresses this by ensuring a constant proportion of acetylene in the gas mixture used for chemical vapour deposition.

The filtered supply of acetylene gas and the supply of the volatile hydrocarbon gas may additionally be mixed with a supply of another gas to provide the gas mixture having the selected proportion of the volatile hydrocarbon. In other words, the mass controller may mix the filtered supply of acetylene gas and the supply of the volatile hydrocarbon gas with a supply of another gas to provide the gas mixture having the selected proportion of the volatile hydrocarbon. The invention encompasses selecting the proportion of the volatile hydrocarbon gas to be substantially zero. However, it is preferred that the selected proportion of volatile hydrocarbon gas is between 0.1% and 25% by mass.

Filtering the supply of acetylene gas preferably comprises passing the acetylene gas over active carbon to remove the volatile hydrocarbon gas. In other words, the filter comprises active carbon over which the supply of acetylene gas is passed to remove the volatile hydrocarbon gas. Filtering with active carbon is a very effective way of removing gaseous volatile organic compounds (that is, volatile hydrocarbon gases), such as gaseous acetone, from a gas mixture. Furthermore, acetylene gas is not absorbed by active carbon, which means that, unlike the dry ice traps described in the prior art, there is no risk of collecting acetylene liquid and the risks associated with handling inadvertently collected acetylene liquid are eliminated. Nevertheless, alternative filters may be used in accordance with the first and second aspects of the present invention, and these include, but are not limited to dry ice traps and zeolite filters.

The use of active carbon filters is considered new in itself and, according to a third aspect of the present invention, there is provided a method of chemical vapour deposition for forming a carbon nanomaterial, the method comprising passing acetylene gas over active carbon to remove a volatile hydrocarbon gas; providing the filtered acetylene gas to a chamber; and performing chemical vapour deposition in the chamber to form the carbon nanomaterial with use of the filtered acetylene gas.

Likewise, according to a fourth aspect of the present invention, there is provided chemical vapour deposition apparatus for forming a carbon nanomaterial, the apparatus comprising a filter comprising active carbon over which acetylene gas is passed to remove a volatile hydrocarbon gas; and an inlet for providing the filtered acetylene gas to a chamber so that chemical vapour deposition can be performed in the chamber to form the carbon nanomaterial with use of the filtered acetylene gas.

The active carbon is usually powdered, although other forms may be used (for example, the activated carbon may be granulated). However, powdered active carbon has a tendency to settle. In other words, the overall volume of the powder may shrink over time when it remains undisturbed. This can result in a space at the top of a chamber in which it is housed containing no powdered active carbon, even if the chamber was initially filled with powdered active carbon. If the chamber is arranged to allow the gas to be filtered to flow through the chamber horizontally, this space can allow the gas to pass through the chamber without passing over the active carbon, or at least not between the particles of the powdered active carbon.

Accordingly, it is preferred that the passing of acetylene gas over active carbon comprises passing the acetylene gas through a chamber housing powdered active carbon and pushing a wall of the chamber inwards such that the powdered active carbon in the chamber moves to fill the entire width of a path through which the acetylene gas passes through the chamber. In other words, the filter preferably comprises a chamber housing powdered active carbon and a wall of the chamber is arranged to push inwards such that the powdered active carbon in the chamber moves to fill the entire width of a path through which the acetylene gas passes through the chamber. This allows the passage of the gas to be horizontal or vertical and improves the reliability of the filtering.

The method and apparatus can be used to form a variety of nanomaterials, such as fullerenes, e.g. in the form of C₆₀, C₇₀, C₇₆, and C₈₄ molecules. They can also be used in the deposition of thin films of various forms of carbon (such as semiconducting or dielectric carbon films, or diamonds). However, they are most applicable to the formation of a carbon nanotube or carbon nanotubes. These may be single walled nanotubes (SWNTs) or multi walled nanotubes (MWNTs).

Preferred embodiments of the invention are described below, by way of example only, with reference to the accompanying drawings.

### BRIEF DESCRIPTION OF DRAWINGS

FIG. 1 is a schematic illustration of a chemical vapour deposition apparatus for forming a carbon nanomaterial, according to a preferred embodiment;

FIG. 2 is a schematic illustration of a filter of the apparatus shown in FIG. 1; and

FIGS. 3A and 3B illustrate the effect of the filter of the apparatus shown in FIG. 1 upon the growth of carbon nanotubes (CNTs).

### DETAILED DESCRIPTION OF PREFERRED EMBODIMENTS

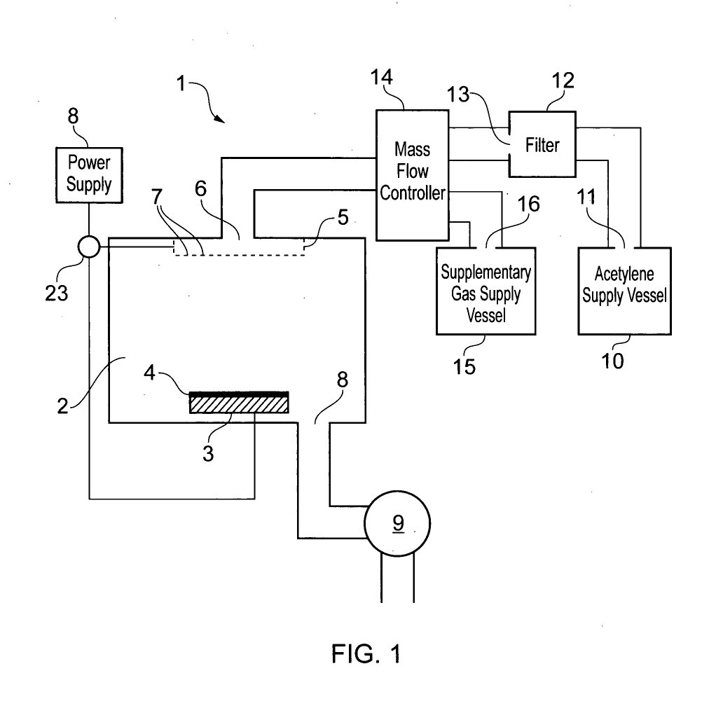

Referring to FIG. 1, an apparatus 1 suitable for thermal chemical vapour deposition (TCVD) or plasma enhanced chemical vapour deposition (PECVD) comprises a chamber 2 housing a chuck 3 on which a substrate 4 is mounted. The chuck 3 is able to act as a heater. The substrate 4 is provided with a metal coating that acts as a catalyst for the growth of a carbon nanomaterial during the chemical vapour deposition (CVD) process. In this embodiment, the substrate 4 is silicon with a nickel (Ni) coating.

At the top of the chamber 2 is a showerhead 5, which functions as a gas inlet and anode. More specifically, the showerhead 5 has an inlet 6 though which it receives feedstock gas for use in the CVD process and a plurality of outlets 7 through which the feedstock gas can pass out of the showerhead 5 and into the chamber 2. The showerhead is preferably metallic. A power supply 8 is provided that can apply a voltage up to around 1000 V to either the chuck 3 or the showerhead 5. In one embodiment, the power supply 8 can apply a direct current (DC) voltage up to around 1000 V. In another embodiment, the power supply can apply an alternating current (AC) voltage up to around 1000 V at a radio or microwave frequency.

A switch 23 is provided for switching the power supply 8 to apply the voltage to the chuck 3 or the showerhead 5. In TCVD, the switch 23 is set such that the power supply 8 applies the voltage to the chuck 3. This provides sufficient power for the chuck 3 to heat the substrate 4. In contrast, in PECVD the switch 23 may be set such that the power supply 8 applies the voltage to either the chuck 3 or the showerhead 5. The plasma struck in PECVD may be used to provide the heating effect provided by the chuck 3 in TCVD.

At the bottom of the chamber 2 is a gas outlet 8 through which gas in the chamber 2 can be evacuated using a vacuum pump 9. In this embodiment, the vacuum pump 9 is a turbo molecular pump. In another embodiment, the vacuum pump 9 is a rotary pump. The vacuum pump 9 is capable of reducing the pressure in the chamber 2 to as low as around 5e-7 Torr.

An acetylene (C₂H₂) supply vessel 10 contains a porous material. A liquid volatile hydrocarbon is provided in the vessel and acetylene gas is dissolved in the volatile hydrocarbon under pressure so that when an outlet 11 of the acetylene supply vessel 10 is opened, a supply of acetylene gas exits the vessel. The volatile hydrocarbon in this embodiment is acetone (CH₃COCH₃). However, it may alternatively be dimethylformamide ((CH3)2NC(O)H) or other suitable materials. The outlet 11 of the acetylene supply vessel 10 is coupled to a filter 12 for filtering the supply of acetylene gas. An outlet 13 of the filter 12 is coupled to a mass flow controller 14. A supplementary gas supply vessel 15 also has an outlet 16 coupled to the mass flow controller 14. The supplementary gas supply vessel 15 provides a supply of supplementary gas. In this embodiment, the supplementary gas is the volatile hydrocarbon gas (which, in this embodiment, is acetone gas). In other embodiments the supplementary gas is a different gas and/or one or more additional supplementary gas supply vessels provide one or more supplies of additional supplementary gas or gases. The additional supplementary gases may include, but are not limited to: hydrogen, nitrogen, ammonia and helium and argon. The mass controller 14 controls the amount of filtered acetylene gas and supplementary gas or gases provided to the inlet 6 of the showerhead 5 as a feedstock gas for the CVD process. The mass controller 14 in this embodiment is arranged to provide feedstock gas in which the proportion of acetone is between 0.1% and 25%. In other embodiments, the proportion of the volatile hydrocarbon may be anything greater than 0.001%, or anything greater than 0.01%. More preferably, in these alternative embodiments, the proportion of the volatile hydrocarbon is between 0.001% and 25%, or between 0.01% and 25%.

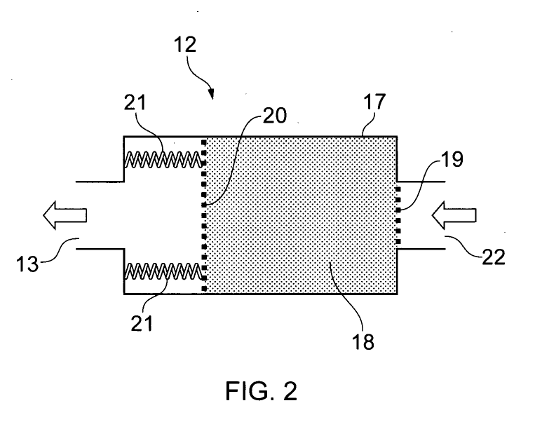

Referring to FIG. 2, the filter 12 comprises a chamber 17 housing powdered active carbon 18. At an inlet 22, the side wall of the chamber 17 comprises a porous membrane 19 that allows the flow of gas from the acetylene supply vessel 10 into the chamber 17, but retains the active carbon within the chamber 17. At the outlet 13, the chamber 17 has another porous membrane 20 that allows the flow of gas from the chamber 17 through the outlet 13 to the mass flow controller 14, but retains the active carbon with the chamber 17. However, the porous membrane 20 at the outlet 13 is slidably mounted in the filter 12 to provide the chamber 17 with a movable wall. A resilient means 21, which in this embodiment is two springs, pushes the porous membrane 20 inwards with respect to the chamber 17. This has the effect of ensuring that the powdered active carbon 18 fills the entire volume of the chamber 17. Gas passing from the inlet 22 to the outlet 13 therefore passes over the active carbon, which has the effect of removing volatile organic compounds in the gas. In particular, any acetone gas that is extracted from the acetylene supply vessel 10 with the acetylene gas is absorbed by the active carbon and substantially no acetone gas is present in the filtered acetylene gas provided to the mass flow controller 14. The same effect is achieved for any other volatile hydrocarbon leaving the acetylene supply vessel 10.

The filter 12 is placed on the acetylene supply vessel 10 side of the mass flow controller 14. This ensures that the action of the vacuum pump 9 on the chamber 2 does not reduce the pressure in the filter 12 to the extent that the acetone evaporates and re-enters the gas supply. However, when the filter 12 is full, the pressure on it is reduced deliberately in order to release the acetone.

In use, the chamber 2 of the CVD apparatus is evacuated by the vacuum pump 9. The mass flow controller 14 then allows the filtered acetylene gas and supplementary gas or gases to flow into the chamber 2 in selected proportions and at a rate that allows the vacuum pump 9 to maintain a substantially constant pressure in the chamber 2. The pressure can alternatively or additionally be controlled using a throttle valve (not shown).

In the case of TCVD, the switch 23 is operated such that the power supply 8 applies a voltage to the chuck 3 in order to heat the substrate 4. The potential difference between the showerhead 5 and the substrate 4 causes ions and reactive species to be transported to the substrate 4 where the growth of carbon nanotubes (CNTs) occurs.

In the case of PECVD, the switch 23 is operated such that the power supply 8 applies a voltage to either the showerhead 5 or the chuck 3. A plasma is struck by the voltage applied by the power supply 8. The plasma can be used to heat the substrate 4 if necessary. As in TCVD, the potential difference between the showerhead 5 and the substrate 4 causes ions and reactive species to be transported to the substrate 4 where the growth of carbon nanotubes (CNTs) occurs.

The advantage of striking a plasma is that it reduces the required operating temperature of the device. TCVD processes typically operate at 450° C. to 1200° C., but PECVD need not operate at such high temperatures. Moreover, the use of PECVD can help form CNTs that are aligned with the electric field.

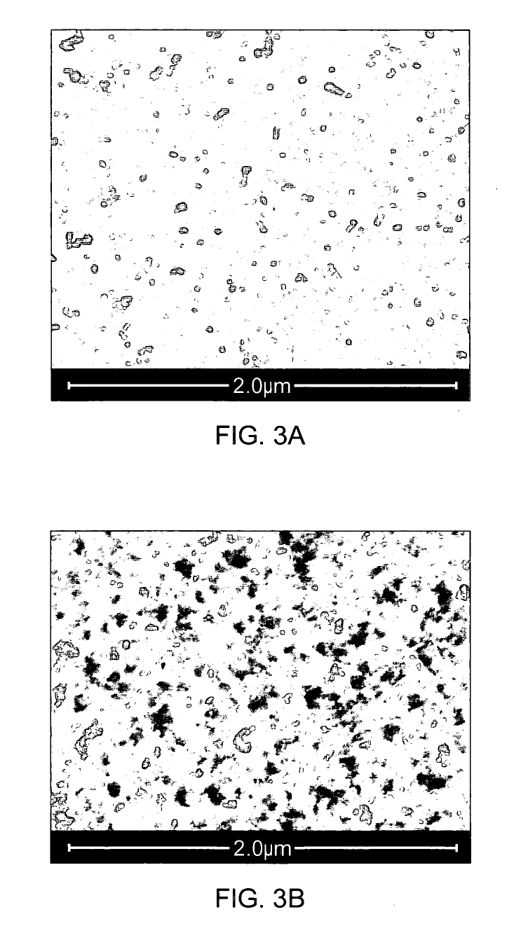

FIGS. 3A and 3B illustrate the effect of filtering the acetylene supply to provide a feedstock gas in the chamber 2 having a constant proportion of acetylene in the manner described above. In the particular example shown, TCVD was employed at a temperature of around 600° C. at a pressure of 5 torr. No acetone was introduced from the supplementary gas supply vessel 16. A 2 mm thick thin film catalyst of sputtered nickel was applied to the substrate to enhance CNT growth. An additional supplementary supply of hydrogen was provided and arranged such that the feedstock gas entering the chamber 2 comprised approximately 95% hydrogen.

FIG. 3A shows the growth of CNTs when no filter 12 was employed, with the result that the supply of acetylene gas from the acetylene supply vessel 10 in the feedstock gas entering the chamber 2 was not filtered. In contrast, FIG. 3B shows the growth of CNTs when a filter 12 was employed to filter the supply of acetylene gas in the manner described above. The yield of CNTs in FIG. 3A is found to be significantly lower than that in FIG. 3B, and it is also found that more amorphous carbon is deposited without the filtering process. This is due to the controlled proportion of acetylene in the feedstock gas provided by the filtering process. The effect illustrated by FIGS. 3A and 3B is even more pronounced when PECVD is used.

The described embodiments of the invention are only examples of how the invention may be implemented. Modifications, variations and changes to the described embodiments will occur to those having appropriate skills and knowledge. These modifications, variations and changes may be made without departure from the scope of the invention defined in the claims and its equivalents.

1. A method of chemical vapour deposition for forming a carbon nanomaterial, the method comprising: filtering a supply of acetylene gas to remove a volatile hydrocarbon gas; mixing the filtered supply of acetylene gas with a supply of the volatile hydrocarbon gas to provide a gas mixture having a selected proportion of the volatile hydrocarbon gas; providing the gas mixture to a chamber; and performing chemical vapour deposition in the chamber to form the carbon nanomaterial with use of the gas mixture.

2. The method of claim 1., comprising mixing the filtered supply of acetylene gas and the supply of the volatile hydrocarbon gas with a supply of another gas to provide the gas mixture having the selected proportion of acetone gas.

3. The method of claim 1, wherein the selected proportion of the volatile hydrocarbon gas is between 0.1% and 25% by mass.

4. The method of claim 1, wherein filtering the supply of acetylene gas comprises passing the acetylene gas over active carbon to remove the volatile hydrocarbon gas.

5. A method of chemical vapour deposition for forming a carbon nanomaterial, the method comprising passing acetylene gas over active carbon to remove a volatile hydrocarbon gas; providing the filtered acetylene gas to a chamber; and performing chemical vapour deposition in the chamber to form the carbon nonmaterial with use of the filtered acetylene gas.

6. The method of claim 4, wherein the passing of acetylene gas over active carbon comprises passing the acetylene gas through a chamber housing powdered active carbon and pushing a wall of the chamber inwards such that the powdered active carbon in the chamber moves to fill the entire width of a path through which the acetylene gas passes through the chamber.

7. The method of claim 1, wherein the nanomaterial is a carbon nanotube.

8. The method of claim 1, wherein the volatile hydrocarbon gas is acetone (CH₃COCH₃) or dimethylformamide ((CH3)2NC(O)H).

9. Chemical vapour deposition apparatus for forming a carbon nanomaterial, the apparatus comprising: a filter for filtering a supply of acetylene gas to remove a volatile hydrocarbon gas; a mass controller for mixing the filtered supply of acetylene gas with a supply of the volatile hydrocarbon gas to provide a gas mixture having a selected proportion of the volatile hydrocarbon gas; and an inlet for providing the gas mixture to a chamber so that chemical vapour deposition can be performed in the chamber to form the carbon nanomaterial with use of the gas mixture.

10. The apparatus of claim 9, wherein the mass controller mixes the filtered supply of acetylene gas and the supply of the volatile hydrocarbon gas with a supply of another gas to provide the gas mixture having the selected proportion of the volatile hydrocarbon gas.

11. The apparatus of claim 9, wherein the selected proportion of the volatile hydrocarbon gas is between 0.1% and 25% by mass.

12. The apparatus of claim 9, wherein the filter comprises active carbon over which the supply of acetylene gas is passed to remove the volatile hydrocarbon gas.

13. Chemical vapour deposition apparatus for forming a carbon nanomaterial, the apparatus comprising a filter comprising active carbon over which acetylene gas is passed to remove a volatile hydrocarbon gas; and an inlet for providing the filtered acetylene gas to a chamber so that chemical vapour deposition can be performed in the chamber to form the carbon nanomaterial with use of the filtered acetylene gas.

14. The apparatus of claim 13, wherein the filter comprises a chamber housing powdered active carbon and a wall of the chamber is arranged to push inwards such that the powdered active carbon in the chamber moves to fill the entire width of a path through which the acetylene gas passes through the chamber.

15. The apparatus of claim 9, wherein the nanomaterial is a carbon nanotube.

16. The apparatus of claim 9, wherein the volatile hydrocarbon gas is acetone (CH₃COCH₃) or dimethylformamide ((CH3)2NC(O)H).

17. (canceled)

18. (canceled)
